(19) United States
(12) Patent Application Publication
(10) Pub. No.: US 2014/0146477 A1
(43) Pub. Date: May 29, 2014

(54) HYBRID SHEET MATERIALS AND METHODS OF PRODUCING SAME

(71) Applicant: ILLINOIS TOOL WORKS INC., Glenview, IL (US)

(72) Inventor: Seung Hoon Youn, Seoul (KR)

(73) Assignee: Illinois Tool Works Inc., Glenview, IL (US)

(21) Appl. No.: 13/687,655

(22) Filed: Nov. 28, 2012

(51) Int. Cl. H05K 9/00; H05K 7/20; B32B 37/12

(52) U.S. Cl. CPC H05K 9/0088; B32B 37/12; H05K 7/20963
USPC 361/705; 427/123; 156/60; 174/388

(57) ABSTRACT

A hybrid sheet material includes an EMI absorption layer bonded to a thermal absorption layer. The EMI absorption layer may include a homogeneous mixture of a binder, silicon, and at least one metal. The thermal absorption layer may include a homogeneous mixture of a graphite material and a binder. According to a further aspect, a mobile device that includes a hybrid sheet material is provided. Other aspects include methods for producing the hybrid sheet material.

### FIELD OF THE TECHNOLOGY

One or more aspects relate generally to hybrid sheet materials, and more particularly to hybrid sheet materials having both electromagnetic interference (EMI) absorption and thermal absorption characteristics.

### SUMMARY

In accordance with one or more embodiments, a hybrid sheet material may comprise an electromagnetic interference (EMI) absorption layer comprising a first binder and at least one metal, and a thermal absorption layer bonded to at least one surface of the EMI absorption layer, the thermal absorption layer comprising a mixture of a graphite material and a second binder.

In accordance with one or more embodiments, a method for producing a hybrid sheet material may comprise providing an electromagnetic interference (EMI) absorption powder mixture comprising a first binder, silicon, and at least one metal, providing a thermal absorption sheet material having a first surface and a second surface and comprising a homogeneous mixture of a graphite material and a second binder, and coating the first surface of the thermal absorption sheet material with the EMI absorption powder mixture to form a hybrid structure.

In accordance with one or more embodiments, an electronic device may comprise a heat producing electronic component and a hybrid sheet material proximate the heat producing electronic component and comprising an electromagnetic interference (EMI) absorption layer comprising a first binder material, silicon, and at least one metal, and a thermal absorption layer bonded to at least one surface of the EMI absorption layer, the thermal absorption layer comprising a graphite material and a second binder.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. The accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF THE DRAWINGS

In the drawings, like reference characters generally refer to the same parts throughout the different views. Also, the drawings are not necessarily to scale, emphasis instead generally placed upon illustrating the principles of the invention and are not intended as a definition of the limits of the invention. For purposes of clarity, not every component may be labeled in every drawing. In the following description, various embodiments of the present invention are described with reference to the following drawings, in which:

FIG. 1 is a cross-sectional view of a hybrid sheet material in accordance with exemplary embodiments disclosed herein;

FIG. 2 is a cross-sectional view of an additional embodiment of a hybrid sheet material in accordance with exemplary embodiments disclosed herein;

FIG. 3 is a graph illustrating the impedance characteristics of a hybrid sheet material in accordance with exemplary embodiments disclosed herein;

FIG. 4 is a graph illustrating the frequency absorbing characteristics of a hybrid sheet material in accordance with exemplary embodiments disclosed herein;

FIG. 5 is a graph illustrating the impedance characteristics of a hybrid sheet material in accordance with exemplary embodiments disclosed herein;

FIG. 6 is a cross-sectional view of a device that includes a hybrid sheet material in accordance with exemplary embodiments disclosed herein; and

FIG. 7 is a cross-sectional view of a device that includes a hybrid sheet material in accordance with exemplary embodiments disclosed herein.

### DETAILED DESCRIPTION

Various embodiments are not limited in their application to the details of construction and the arrangement of components as set forth in the following description or illustrated in the drawings. The invention is capable of embodiments and of being practiced or carried out in various ways beyond those exemplarily presented herein.

In accordance with one or more embodiments, a hybrid sheet material may be provided. In certain embodiments, the hybrid sheet material may be constructed and arranged to absorb both thermal and EMI forms of energy. The hybrid sheet material may be flexible, thin, and capable of conforming to a mating surface. The hybrid sheet material may offer several advantages, including reducing the number of steps involved in a manufacturing process. For example, an existing process may require separate steps during which discrete thermal absorption and EMI absorption materials are layered in a device. Each of these layers may be cut or sized in separate steps. Furthermore, each material may require one or more layers of adhesive and/or cover film which may have to be separately laminated or attached to the underlying structure. These steps may add time and expense to the manufacturing process. Providing thermal and EMI absorption properties in a single sheet material in accordance with one or more embodiments may beneficially reduce the time and expense for a manufacturing process. Further, providing a single hybrid sheet material instead of two separate sheet materials may reduce the overall thickness. This may provide the additional advantage of reducing the size and weight of a device that uses the hybrid sheet material. For example, one or more layers of adhesive and/or cover film may be eliminated from a manufacturing process when the hybrid sheet material is used. In some non-limiting embodiments, eliminating these layers of material may reduce the overall thickness of a device by about 10 μm to about 80 μm. Disclosed hybrid sheet materials may be RoHS compliant and substantially halogen-free. In some specific embodiments, a hybrid sheet material may generally include a metal rubber layer and a natural or synthetic graphite layer as discussed herein.

As used herein, the term “sheet” includes within its meaning any material in the form of a flexible web, strip, paper, tape, foil, film, mat, or the like. The term “sheet” additionally includes any substantially flat material or stock of any length and width. For example, the sheet may be available in a roll format or a stacked format. In one specific non-limiting example, the sheet may be available in an A4 sized format. The sheet may be cut to size depending on an intended operation, such as in a device manufacturing process.

In accordance with one or more embodiments, a hybrid sheet material may find applications in association with various heat generating components. Non-limiting examples of heat generating components include wireless or mobile communication devices, display devices, such as LCD displays, computer-related devices, such as printed circuit boards, power amplifiers, central processing units, graphic processing units, and memory modules, batteries or power supplies, or any other electronic apparatus that comprises a heat generating component. In certain embodiments, the hybrid sheet material may be positioned adjacent to or near one or more heat generating components.

In accordance with one or more embodiments, a hybrid sheet material may include an EMI absorption layer. The terms “EMI absorption layer,” “EMI absorption material,” “EMI absorption sheet material” “frequency absorption layer” and like terms may be used interchangeably. As used herein, the term “EMI” may be considered to refer generally to both EMI and radio frequency interference (RFI) emissions. The use of the term “EMI absorption” in connection with various embodiments disclosed herein is to be understood to encompass the absorption and reduction of electromagnetic fields that can contribute to EMI. The term “metal rubber sheet” may also be used to refer to the EMI absorption layer.

In at least some embodiments, the EMI absorption layer may include one or more materials. In certain non-limiting embodiments, the EMI absorption layer may comprise silicon. The silicon may be in any physical or chemical form that is suitable for the purposes of performing or contributing to the performance of the EMI energy absorption characteristics of the embodiments disclosed herein. In some embodiments, the silicon may be provided in powder form. As used herein, the term “powder” includes crystalline forms of one or more materials. In certain embodiments, the EMI absorption layer may include between about 1 and 25 percent by weight. In at least one embodiment, the EMI absorption layer may comprise between about 15 and 25 percent silicon by weight. In other embodiments, the EMI absorption layer may be from about 1 and 10 percent silicon by weight.

In accordance with one or more embodiments, the EMI absorption layer may include a binder material. As used herein, the term “binder material” or simply “binder” refers to a material that is generally capable of mechanically and/or chemically bonding one or more materials together. Non-limiting examples of binder material include urethane, polyurethane, epoxies and acrylics. In at least one embodiment, the binder material may be a resin material comprising polyurethane or urethane. In various embodiments, the binder material may be provided in a powder form but other forms are possible. In at least one aspect, the EMI absorption layer may include from between about 5 and about 20 percent by weight of binder. In some embodiments, the EMI absorption layer may include between about 5 and about 15 percent by weight of binder. In other embodiments, the binder may be from about 10 to about 20 percent by weight.

In accordance with one or more embodiments, the EMI absorption layer may include at least one metal. In some embodiments, the metal may comprise an alloy. In other embodiments, the metal may comprise iron and at least one alloy. In various embodiments, the metal may comprise at least one of iron, aluminum, and chromium. In at least one specific embodiment, the metal component comprises iron and aluminum. In another specific embodiment, the metal component comprises iron and chromium. An example of an additional metal that may be included in the EMI absorption layer includes copper. The metal may be any metal that is suitable for the purposes of performing or contributing to the performance of the EMI energy absorption properties as described herein. The EMI absorption layer may include silicon in accordance with one or more embodiments.

In some embodiments, the metal component may be provided in powder form. In other embodiments, the metal component may be provided in flake or flake-like form. As used herein, the term “flake” may be defined as a particle of substantially uniform thickness and having an irregular planar shape with a diameter that is greater than the thickness. Providing the metal in a flake form may allow for a unidirectional arrangement of the flakes on a substrate. The flakes may be laminated using a thin film sheet production technique.

In at least one embodiment, the EMI absorption layer comprises between about 5 and 10 percent by weight of aluminum. In another embodiment, the EMI absorption layer comprises between about 1 and 10 percent by weight of chromium. In a further embodiment, the EMI absorption layer comprises between about 45 and 90 percent by weight of iron. In at least one embodiment, iron may be between about 45 and 55 percent by weight. In another embodiment, iron may be between about 70 and 90 percent by weight.

In various embodiments, the EMI absorption layer may include a mixture of a binder material, silicon, and at least one metal. In some aspects, the mixture may be homogeneous. As used herein, the term “homogeneous” when used to describe a mixture, refers to a substantially single-phase composite of two or more compounds that are distributed in a uniform ratio or in a substantially uniform ratio throughout the mixture so that any portion of the composite exhibits the same ratio of the two or more compounds. In at least one aspect, the mixture may be a powder mixture. In some aspects, the powder mixture may be provided by milling one or more components using a mechanical process. The powder mixture may then be dried in an oven. In certain aspects, the mixture that is milled and dried is further mixed with one or more additional components. For example, silicon and at least one metal may be milled together to make a flaky powder. This flaky mixture may then be dried in an oven and then mixed with a binder, such as a resin material, in a mixing process. The flaky mixture may be mixed together after being dried and before being combined with the binder material.

According to one or more aspects, the EMI absorption layer may be effective for absorbing at least a portion of electromagnetic waves having a frequency from about 1 MHz to about 6 GHz. In certain aspects, the EMI absorption layer may be effective from about 200 MHz to about 3 GHz. The frequency absorption properties of the EMI absorption layer may be a function of the thickness of the layer and/or the proportions and selection of materials used to construct the EMI absorption layer, such as the ratios and amount of metal used. These properties may be used to target a specific range of frequencies by varying the thickness of the EMI absorption layer and/or varying the amount and choice of materials.

In various non-limiting embodiments, the EMI absorption layer may include one or more discrete sub-layers. In at least one embodiment, one or more sub-layers that are from about 40 to about 60 microns in thickness each may be pressed together at a specific temperature, pressure, and time. For example, five individual sheets that are each 60 microns in thickness may be pressed together at a given temperature and pressure for one hour, yielding a final sheet that is 150-200 microns in thickness.

According to one or more embodiments, the EMI absorption layer may be commercially available from various manufacturers. For example, the EMI absorption layer may be obtained from EMPKO of Kyunggi-Do, South Korea. Suitable products available from EMPKO include the AH-N-5000, AH-N-6000, AH-4000, and AH-7000 series of products. Other suitable material may be provided by the NH-XX series of products manufactured by ChangSung Corp. of Inchen, South Korea. Other manufacturers of suitable EMI absorption materials include Chemtronics Co., Ltd of Chungcheongnam-Do, South Korea.

The thickness of the EMI absorption layer may be any thickness that is suitable for the purposes of functioning as an EMI energy absorber as described herein. In accordance with one or more embodiments, the EMI absorption layer may have a thickness of from about 10 μm to about 2,000 μm. In some embodiments, the EMI absorption layer may have a thickness of from about 50 microns to about 500 microns. In some specific embodiments, the EMI absorption layer may have a thickness from about 10 microns to about 400 microns. In at least one embodiment, the EMI absorption layer may have a thickness of about 50 microns. In various embodiments, the EMI absorption layer may be provided in a sheet format, as previously discussed.

In accordance with one or more embodiments, the hybrid sheet material may include a thermal absorption layer. The terms “thermal absorption layer,” “thermal absorption material,” and “thermal absorption sheet material” may be used interchangeably. The use of the term “thermal absorption” in connection with the embodiments disclosed herein is to be understood to encompass the absorption and reduction of thermal energy. In some embodiments, the thermal absorption layer may function as a heat sink. In other embodiments, the thermal absorption layer may be interposed between a heat sink and a heat generating component and may function to direct thermal energy from the heat generating component to the heat sink.

In various embodiments, the thermal absorption layer may be constructed and arranged to serve as a flexible heat-spreading material. For example, within the thermal absorption layer, heat may laterally spread out such that there may be more surface area from which heat may be transferred either through conduction and/or convection to air or any other ambient environment. The greater surface area due to the lateral spreading of the heat may increase and improve the heat transfer efficiency associated with the thermal absorption layer.

In at least one embodiment, the thermal absorption layer may comprise a graphite material. Non-limiting examples of graphite material may include exfoliated graphite or compressed particles of exfoliated graphite formed from intercalating and exfoliating graphite flakes. Additional examples of graphite may include natural graphite, synthetic graphite, pyrolytic carbon, graphene, and fullerene. The graphite material may be present in any form that functions to enhance the thermal absorbing properties of the embodiments disclosed herein. Copper and aluminum may also be used.

In accordance with one or more embodiments, the thermal absorption layer may include a binder. In certain embodiments, the thermal absorption layer may be a homogeneous mixture of a graphite material and a binder. Non-limiting examples of binders may include urethane, polyurethane, and epoxy resin. In at least one embodiment, the binder material may be a resin material comprising polyurethane or urethane. A composite binder, such as polycarsol may be used in some embodiments. The binder may be any thermally conductive binder that is suitable for the purposes of performing or enhancing the thermal spreading function of the thermal absorption layer.

In various embodiments, the thermal absorption layer may comprise over 99% graphite by weight. In certain embodiments, the amount of graphite that is present in the thermal absorption layer is directly linked to the thermal properties of the layer. For example, the more graphite that is present, the greater the heat spreading functionality of the thermal absorption layer. In various embodiments, the thermal absorption layer may comprise only graphite, i.e., is 100% graphite by weight.

According to one or more other embodiments, the thermal absorption layer may be commercially available from various manufacturers. For example, the thermal absorption layer may be obtained from GrafTech International of Parma, Ohio. Suitable products available from GrafTech include the eGRAF® SPREADERSHIELD™ line of flexible graphite materials, including the SS400, SS500, SS600, SS1500 and SS1700 series of products. Other sources for the thermal absorption layer may include one or more materials from the PGS® line of products from Panasonic Corp. of Osaka, Japan. Additional sources of material may also include the Graphinity™ line of products available from Kaneka Corp. of Osaka, Japan and the TGS™ series of products from Tanyuan Technology Development Co. of Changzhou, China. In at least some embodiments, the EMI absorption layer may be applied directly to the thermal absorption layer. Thus, the thermal absorption layer may serve as a substrate for an EMI absorption layer as discussed below.

The thickness of the thermal absorption layer may be any thickness that is suitable for the purposes of performing as a thermal energy absorber as described herein. According to one or more embodiments, the thermal absorption layer may have a thickness ranging from about 10 microns to about 200 microns. In some embodiments, the thickness may range from about 12 microns to about 100 microns. In certain embodiments, the thermal absorption layer may be from about 30 to about 40 microns in thickness. In at least one embodiment, the thermal absorption layer may have a thickness of about 35 microns. In certain embodiments, the thermal absorption layer may have a thickness that is less than 12 microns. The thermal absorption layer may be any thickness that is suitable for the purpose of performing a thermal spreading function as described in the compositions and methods disclosed herein.

According to one or more embodiments, the hybrid sheet material may further include an adhesive layer. As used herein, the terms “adhesive layer” and “adhesive material” may be used interchangeably. The adhesive layer may be applied to at least one surface of the EMI absorption layer and/or the thermal absorption layer. Non-limiting examples of adhesive materials include double-sided (D/S) tape, single-sided (S/S) tape, and pressure-sensitive adhesive. The adhesive layer may facilitate attachment of the hybrid sheet material to a device or other surface. Suitable adhesives may be obtained from manufacturers such as 3M, of St. Paul, Minn., Tesa AG of Hamburg, Germany, and Nitto Denko Corp. of Osaka, Japan, including acrylic, silicone, or rubber types of adhesives. In various embodiments, an acrylic adhesive layer may be used.

In accordance with some embodiments, the hybrid sheet material may further comprise an anti-fingerprint film. In some embodiments, the anti-fingerprint film may be attached or be applied with the adhesive material. In the alternative, the anti-fingerprint film may be attached or applied to the hybrid sheet material or a component of the hybrid sheet material.

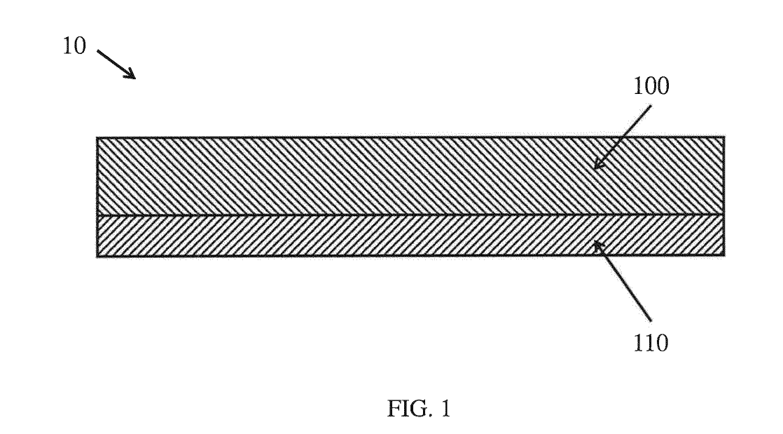

FIG. 1 depicts a perspective view of a hybrid sheet material 10 in accordance with one or more embodiments. In various embodiments, hybrid sheet material 10 includes at least one EMI absorption layer 100. EMI absorption layer 100 may be provided and characterized as previously discussed. The hybrid sheet material 10 may further include at least one thermal absorption layer 110, which may be provided as discussed and described above. In certain embodiments, the thermal absorption layer 110 is bonded to at least one surface of the EMI absorption layer 100. The thermal absorption layer 110 may be bonded to the entire surface of the EMI absorption layer, or may be bonded to a portion thereof. In alternative embodiments, an additional layer of thermal absorption material may be bonded to a second surface of the EMI absorption layer, such that the EMI absorption layer is encapsulated or at least partially surrounded by the thermal absorption material.

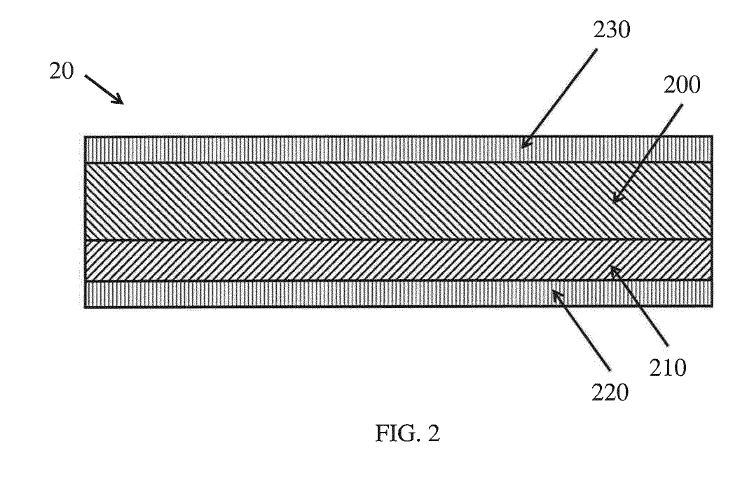

FIG. 2 depicts a perspective view of another hybrid sheet material 20 in accordance with one or more embodiments. The figure illustrates an EMI absorption layer 200 bonded to a thermal absorption layer 210 with adhesive layers 230 and 220 disposed on a surface of both layers. In the alternative, the adhesive layer may be disposed on a surface of only one of the layers. The hybrid sheet material may include one or more thermal absorption layers and one or more EMI absorption layers. For example, the hybrid sheet material may comprise a thermal absorption layer that is layered between two EMI absorption layers. In the alternative, the hybrid sheet material may comprise an EMI absorption layer that is positioned in between two thermal absorption layers. The EMI absorption, thermal absorption, and adhesive layers may be arranged in any configuration that is suitable for functioning as a thermal and frequency absorbing material as disclosed herein.

In accordance with one or more embodiments, a method for producing a hybrid sheet material is provided. In at least one embodiment, the method may involve providing a thermal absorption sheet material. The thermal absorption sheet material may be provided and characterized as previously discussed. The thermal absorption sheet material may have a first surface and a second surface. The method may further involve providing an EMI absorption material. The EMI absorption material may include, by way of non-limiting example, a binder, silicon, and at least one metal. The EMI absorption material may be provided as discussed and described above. In some embodiments, the EMI absorption material may be a powder. The method may further involve applying the EMI absorption material to a first surface of the thermal absorption sheet material to form a hybrid structure. In some embodiments, the EMI absorption material may be applied as a powder at a thickness from about 5 μm to about 100 μm. At least a portion of the thermal absorption sheet material may be coated with the EMI absorption material. Examples of suitable coating methods that may be used include comma coating, gravure coating, and micro-gravure coating. In at least one embodiment, the EMI absorption material may be arranged in a unidirectional pattern onto the thermal absorption sheet. As used herein, the term “unidirectional” designates the orientation of the powder mixture as being substantially all in the same direction within a particular sheet, film or layer. For example, the powder mixture may comprise flakes, where the longitudinal axis of each flake is arranged to be parallel to other flakes in the layer. In various embodiments, the size of the flakes and the method used for coating with the powder mixture ensures that a unidirectional pattern is achieved.

In accordance with one or more embodiments, the hybrid structure may be bonded to form a hybrid sheet material. In certain embodiments, bonding may be achieved by a process that involves pressing the hybrid structure at a temperature from about 80° C. to about 200° C. for a period of time ranging from about 30 minutes to about two hours. In a further aspect, the pressure used in bonding the hybrid structure may be from about 1400 psi to about 2100 psi. The pressure used may be dependent upon the thickness of the hybrid structure. In various embodiments, the process may yield a hybrid sheet material with a thickness ranging from about 50 μm to about 400 μm.

In accordance with one or more embodiments, the method may further involve laminating the hybrid sheet material with a pressure sensitive adhesive. The pressure sensitive adhesive may be any one or more of the adhesive materials previously discussed and may have a thickness ranging from about 5 microns to about 50 microns. For example, the pressure sensitive adhesive may be an acrylic, silicone, rubber adhesive, or tape material. In various embodiments, the laminating process may occur at room temperature and at pressures of about 1 kg/25 mm or at pressures of at least about 1 kg/25 mm.

In certain other embodiments, a method for producing a hybrid sheet material includes attaching at least one layer of an EMI absorption material to at least one layer of a thermal absorption material. Each layer may be separately manufactured and then each may be bonded. An adhesive may be applied to a single side of the thermal absorption material and then the EMI absorption material may be placed on top of the thermal absorption material to produce a layered material. The adhesive may then be allowed to cure. In addition, the layered material may be pressurized, for example, by running the material through a pair of rollers. The layered material may be pressurized at a certain temperature for a specified period of time. Additional layers of adhesive and EMI absorption or thermal absorption material may be attached to form the hybrid sheet material. In various embodiments, a protective liner or liners may be disposed over the adhesive layer. The protective liner may be removed prior to or after a further processing step, or may be removed prior to use.

In some embodiments, the EMI absorption material may include one or more sub-layers, as previously discussed. For example, for applications requiring a high degree of permeability, several EMI sub-layers may be pressed together. In certain embodiments, the thermal absorption material may be placed on the top of one of the sub-layers and the entire assembly may be subjected to a specified pressure, temperature, and duration of time. For example, in some embodiments, several EMI sub-layers may be pressed together. These sub-layers may then be bonded to a thermal absorption layer. A top surface of the EMI absorption layer may further include an adhesive layer.

In accordance with one or more embodiments, an electronic device is provided. Examples of an electronic device may include a mobile device. As used herein, the term “mobile device” refers to electronic devices that are adapted to be transported on one's person, including multimedia smartphones, multi-purpose tablet computing devices, portable media players, personal digital assistants (PDAs), electronic book readers, and the like. In certain embodiments, the mobile device includes a heat producing electronic component. As used herein, the term “heat producing” is defined to mean that a device or component possesses the capability of producing thermal energy. Various non-limiting examples of heat producing components include batteries and display panels.

In various aspects, the electronic device may comprise components that enable the electronic device to communicate through one or more analog or digital wireless links, such as Bluetooth, Wi-Fi, NFC, Felica, RFID, Wireless USB, WiMax, wireless charging antenna, or any combination thereof. In some aspects, the electronic device may comprise flexible printed circuit boards (FPCB), including digitizer FPCBs. The digitizer may further comprise a touchscreen panel (TSP), or any other type of display panel that possesses pressure sensitivity characteristics.

According to one or more embodiments, the electronic device may include a hybrid sheet material as disclosed herein. The hybrid sheet material may be configured and provided as previously discussed. In some embodiments, the heat producing electronic component is a display panel positioned above the EMI absorption layer of the hybrid sheet material. In another aspect, the electronic device comprises a near field communication (NFC) antenna. The NFC antenna may be positioned adjacent the EMI absorption layer of the hybrid sheet material. In the alternative, the NFC antenna may be positioned adjacent the thermal absorption layer of the hybrid sheet material. In a further aspect, the heat producing electronic component may be a battery or battery component, such as a battery cover, that may be positioned adjacent the NFC antenna. In a further aspect, the electronic device may comprise an adhesive material that is positioned between the battery and the NFC antenna. The electronic device may comprise an additional adhesive material that is positioned between the EMI absorption layer and the NFC antenna. In various embodiments, the electronic device may comprise a wireless charging antenna. The wireless charging antenna may be positioned adjacent the EMI absorption layer of a hybrid sheet material, or in the alternative, be positioned adjacent the thermal absorption layer. In one or more embodiments, one or more layers of hybrid sheet material may be used in the electronic device. The layers may be separated from one another, or stacked. The wireless charging antenna may be positioned adjacent to any one or more of these layers.

### EXAMPLES

The embodiments described herein will be further illustrated through the following examples, which are illustrative in nature and are not intended to limit the scope of the disclosure.

### Example 1

### High Permeability EMI Absorption Layer

The physical and compositional properties of an exemplary EMI absorption sheet material in accordance with embodiments disclosed herein are presented below in Table 1.

TABLE 1
High permeability EMI absorption layer

| Component Name | % by weight |
|---|---|
| Urethane Binder | 10-20 |
| Silicon Powder | 15-25 |
| Aluminum Powder | 5-10 |
| Iron Powder | 45-55 |
| Thickness (mm) | 0.1-0.3 |
| Sheet Size | A4 |
| Permeability (at 1 MHz) (μ′) | 110 |
| Permeability (at 13.56 MHz) (μ′) | 100 |
| Permeability (at 13.56 MHz) (μ″) | 35 |
| Temperature range (° C.) | −25-125 |
| Specific gravity (g/cm³) | 3.3 ± 0.3 |
| Surface resistance (min.) (Ω) | 1.0 × 10⁸ |
| Thermal conductivity (W/m · K) | 0.8 ± 0.1 |
| Tensile strength (kg/cm²) | >100 |
| Elongation (%) | >60 |

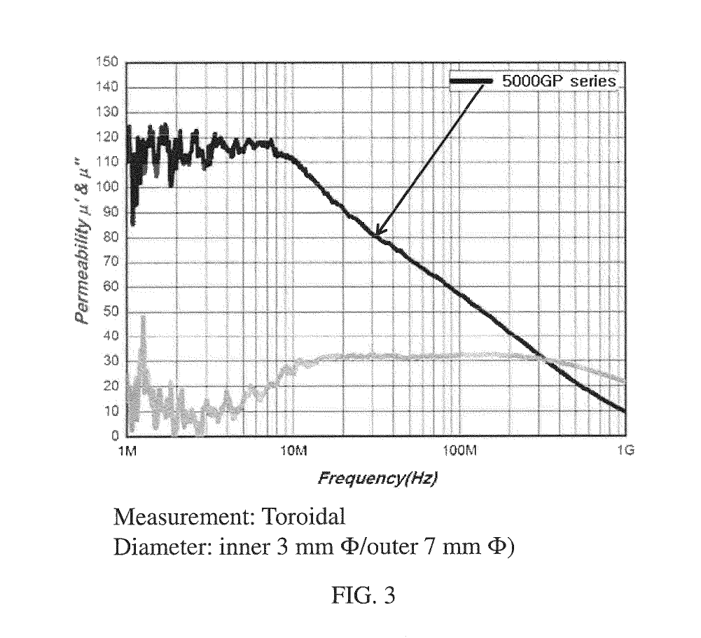

Impedance measurements were taken on an Agilent E4991A (Agilent Technologies, Santa Clara, Calif.) analyzer over a range of frequencies from 1 MHz to 1 GHz. The results are shown in FIG. 3. As shown, permeability of the material decreased in the range of from about 10 MHz to about 1 GHz.

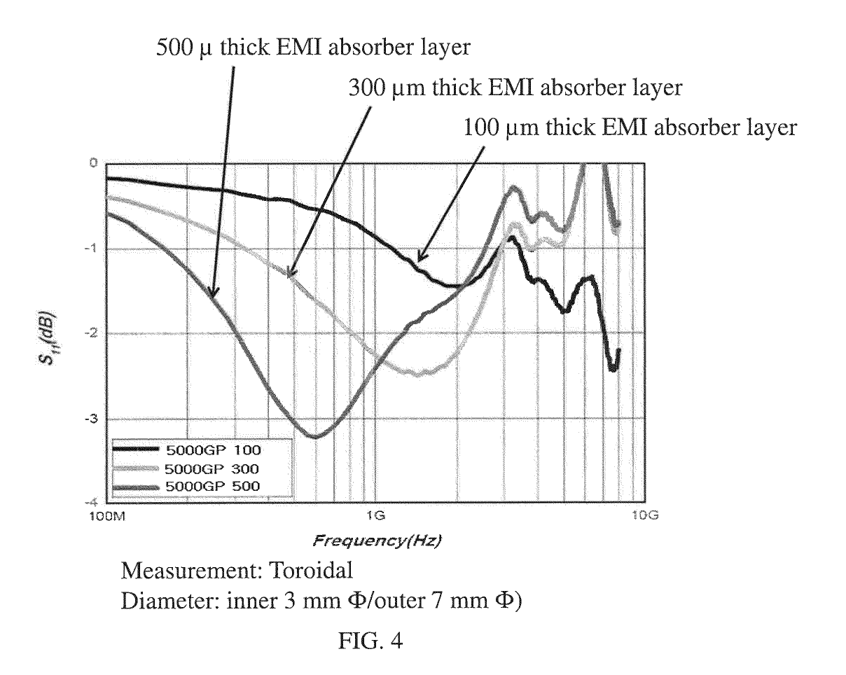

Surface resistivity measurements for three samples of different thicknesses were taken using an Advantest R3767CG network analyzer (Advantest Corporation, Tokyo, Japan). The results for the 100 micron, 300 micron, and 500 micron thickness samples are shown in FIG. 4. As illustrated, the frequency absorbing characteristics vary with the thickness of the material. For example, the 500 micron thick sample exhibited frequency absorbing characteristics from about 300 MHz to about 1.5 GHz, while the 300 micron thick sample exhibited frequency absorbing characteristics from about 600 MHz to about 2.5 GHz.

### Example 2

### Non-Halogen EMI Absorption Layer

The physical and compositional properties of a second exemplary EMI absorption sheet material in accordance with the embodiments disclosed herein are presented below in Table 2.

TABLE 2
Non-Halogen EMI absorption layer

| Component Name | % by weight |
|---|---|
| Polyurethane resin Binder | 5-15 |
| Silicon Powder | 1-10 |
| Chromium Powder | 1-10 |
| Iron Powder | 70-90 |
| Thickness (mm) | 0.1-0.5 |
| Sheet Size | A4 |
| Permeability (at 13.56 MHz) (μ′) | 55 |
| Temperature range (° C.) | −25-125 |
| Specific gravity (g/cm³) | 3.7 ± 0.3 |
| Surface resistance (min.) (Ω) | 1.0 × 10⁶ |
| Thermal conductivity (W/m · K) | 0.8 ± 0.1 |
| Tensile strength (kg/cm²) | >100 |
| Elongation (%) | >60 |

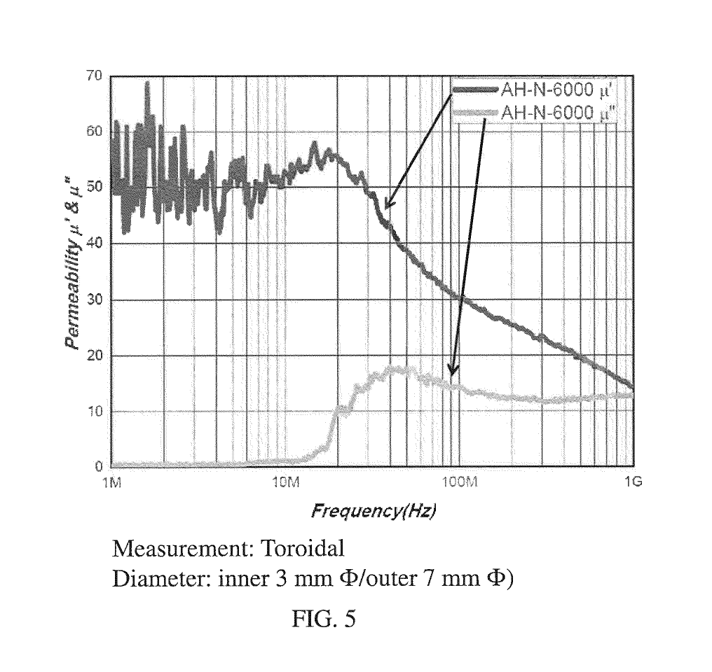

Impedance measurements were taken on an Agilent E4991A analyzer over a range of frequencies from 1 MHz to 1 GHz. The results are shown in FIG. 5 and indicate that permeability of the material decreased in the range of from about 40 MHz to about 1 GHz.

### Example 3

### Hybrid Sheet Material

The physical characteristics of an exemplary hybrid sheet material in accordance with the embodiments disclosed herein are presented below in Table 3.

TABLE 3
Hybrid sheet material

| | |
|---|---|
| Thermal absorption layer | 0.035 |
| thickness (mm) | |
| EMI absorption layer | 0.100, 0.200, |
| thickness (mm) | 0.300 |
| Sheet Size | A4 |
| Permeability (at 1 MHz) (μ′) | 50, 60, 100, 150 |
| Temperature range (° C.) | −25-125 |
| Specific gravity (g/cm³) | 3.5 ± 0.3 |
| Surface resistance of EMI | 1.0 × 10⁸ |
| absorbing layer (min.) (Ω) | |
| Thermal conductivity of EMI | 0.8 ± 0.1 |
| absorption layer (W/m · K) | |
| Thermal conductivity of thermal | 500 ± 100 |
| absorption layer (W/m · K) | |
| Tensile strength (kg/cm²) | >100 |
| Elongation (%) | >60 |

### Example 4

### Electronic Device Comprising an NFC Antenna

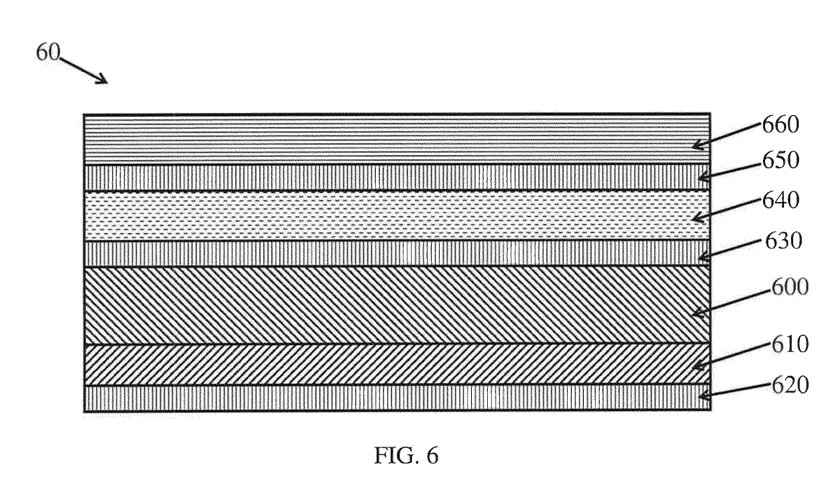

An exemplary electronic device that includes a hybrid sheet material in accordance with one or more embodiments is illustrated in FIG. 6. As shown, a cross-sectional view of an electronic device 60, such as a cell phone, is represented. The device 60 comprises a battery 660 and an NFC antenna 640. The battery 660 may be enclosed in a case. The hybrid sheet material includes an EMI absorption layer 600 bonded to a thermal absorption layer 610. The hybrid sheet material also includes a layer of adhesive on the top 630 and bottom 620 thereof. The top adhesive layer 630 may comprise 5-30 micron D/S tape. The bottom adhesive layer 620 may comprise 5-30 micron D/S or S/S tape. The NFC antenna 640 is positioned adjacent the EMI absorption layer 600 of the hybrid sheet material, with the adhesive layer 630 functioning to hold the two components together in place. Another adhesive layer 650 is attached to the top of the NFC antenna 640. Adhesive layer 650 may comprise D/S tape. The battery 660 is positioned adjacent the NFC antenna 640, with the adhesive layer 650 disposed in between. The electronic device may exhibit one or more benefits from incorporating the hybrid sheet material. For example, at least one layer of D/S tape and cover film may be eliminated from the device, reducing the overall thickness and manufacturing costs.

### Example 5

### Electronic Device Comprising a Display Panel

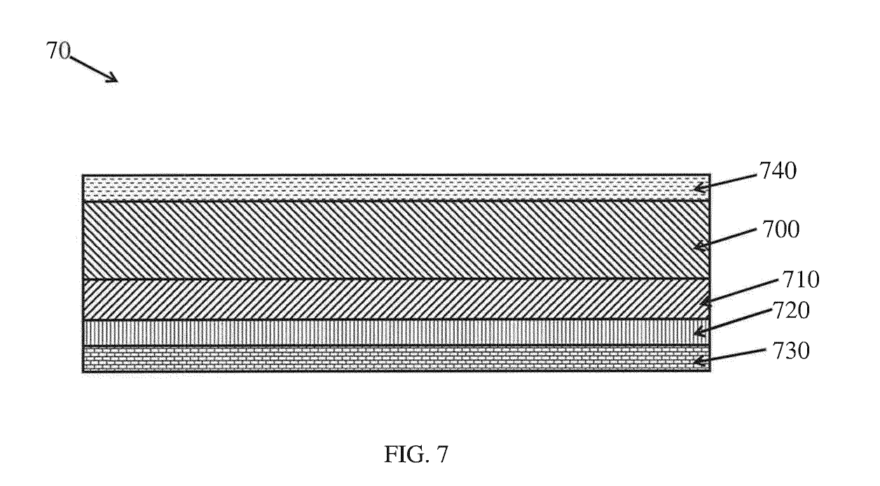

A second exemplary electronic device that includes a hybrid sheet material in accordance with one or more embodiments is illustrated in FIG. 7. In FIG. 7, a cross-sectional view of an electronic device 70 comprising a display device 740 is shown. As used herein, the term “display device” refers to a display panel in which a plurality of pixels are arranged in a matrix shape, and image information is visually transmitted. In at least one embodiment, the display device 740 may be an LCD device. The hybrid sheet material includes an EMI absorption layer 700 bonded to a thermal absorption layer 710. In the illustrated configuration, the display device 740 is positioned adjacent the EMI absorption layer 700 of the hybrid sheet material. An adhesive layer 720 is attached to the thermal absorption layer 710 of the hybrid sheet material. The adhesive layer 720 may comprise 5-30 micron D/S tape. A stainless steel (SUS) sheet 730 is attached adjacent the thermal absorption layer 710, with the adhesive layer 720 disposed in between. Including the hybrid sheet material into the mobile device may reduce the number of steps involved in the assembly process. For example, the sizing, and laminating steps involved in the process may be reduced, as well as the layers and/or amount of material used in the process.

The embodiments disclosed herein are not limited in their application to the details of construction and the arrangement of components set forth in the description or illustrated in the drawings. The invention is capable of other embodiments and of being practiced or of being carried out in various ways. Also, the phraseology and terminology used herein is for the purpose of description and should not be regarded as limiting. The use of “including,” “comprising,” “involving,” “having,” “containing,” “characterized by,” “characterized in that,” and variations thereof herein is meant to encompass the items listed thereafter, equivalents thereof, as well as alternate embodiments consisting of the items listed thereafter exclusively. Use of ordinal terms such as “first,” “second,” “third,” and the like in the claims to modify a claim element does not by itself connote any priority.

While exemplary embodiments have been disclosed many modifications, additions, and deletions may be made therein without departing from the spirit and scope of the disclosure and its equivalents, as set forth in the following claims.

Those skilled in the art would readily appreciate that the various parameters and configurations described herein are meant to be exemplary and that actual parameters and configurations will depend upon the specific application for which the embodiments directed toward the hybrid sheet material of the present disclosure are used. Those skilled in the art will recognize, or be able to ascertain using no more than routine experimentation, many equivalents to the specific embodiments described herein. For example, those skilled in the art may recognize that embodiments according to the present disclosure may further comprise a network of compositions or be a component of a production process using the hybrid sheet material. It is, therefore, to be understood that the foregoing embodiments are presented by way of example only and that, within the scope of the appended claims and equivalents thereto, the disclosed hybrid sheet materials and methods may be practiced otherwise than as specifically described. The present materials and methods are directed to each individual feature or method described herein. In addition, any combination of two or more such features, apparatus or methods, if such features, apparatus or methods are not mutually inconsistent, is included within the scope of the present disclosure.

Further, it is to be appreciated various alterations, modifications, and improvements will readily occur to those skilled in the art. Such alterations, modifications, and improvements are intended to be part of this disclosure, and are intended to be within the spirit and scope of the disclosure. For example, an existing process may be modified to utilize or incorporate any one or more aspects of the disclosure. Thus, in some embodiments, embodiments may involve connecting or configuring an existing process to comprise the hybrid sheet material. For example, an existing manufacturing process may be retrofitted to involve use of a hybrid sheet material in accordance with one or more embodiments. Accordingly, the foregoing description and drawings are by way of example only. Further, the depictions in the drawings do not limit the disclosures to the particularly illustrated representations.

What is claimed is:

1. A hybrid sheet material comprising:
an electromagnetic interference (EMI) absorption layer comprising a first binder and at least one metal; and
a thermal absorption layer bonded to at least one surface of the EMI absorption layer, the thermal absorption layer comprising a mixture of a graphite material and a second binder.

2. The hybrid sheet material of claim 1, wherein the metal of the EMI absorption layer comprises at least one of iron, aluminum, and chromium.

3. The hybrid sheet material of claim 1, wherein the EMI absorption layer has a thickness of from about 50 microns to about 500 microns.

4. The hybrid sheet material of claim 3, wherein the thermal absorption layer has a thickness of from about 10 to about 200 microns.

5. The hybrid sheet material of claim 1, wherein the EMI absorption layer comprises:
between about 10 and 20 percent by weight of the first binder;
between about 15 and 25 percent by weight of the silicon;
between about 5 and 10 percent by weight of aluminum; and
between about 45 and 55 percent by weight of iron.

6. The hybrid sheet material of claim 1, wherein the EMI absorption layer comprises:
between about 5 and 15 percent by weight of the first binder;
between about 1 and 10 percent by weight of the silicon;
between about 1 and 10 percent by weight of chromium; and
between about 70 and 90 percent by weight of iron.

7. The hybrid sheet material of claim 1, wherein the EMI absorption layer is characterized by a capacity to absorb at least a portion of electromagnetic waves having a frequency from about 1 MHz to about 6 GHz.

8. The hybrid sheet material of claim 1, further comprising an adhesive layer formed on at least one surface of the EMI absorption layer or the thermal absorption layer.

9. A method for producing a hybrid sheet material comprising:
providing an electromagnetic interference (EMI) absorption powder mixture comprising a first binder, silicon, and at least one metal;
providing a thermal absorption sheet material having a first surface and a second surface and comprising a homogeneous mixture of a graphite material and a second binder; and
coating the first surface of the thermal absorption sheet material with the EMI absorption powder mixture to form a hybrid structure.

10. The method of claim 9, further comprising bonding the hybrid structure at a temperature from about 80° C. to about 200° C. for a period of time ranging from about 30 minutes to about 2 hours.

11. The method of claim 10, further comprising bonding the hybrid structure at a pressure from about 1400 psi to about 2100 psi.

12. The method of claim 11, further comprising laminating the hybrid sheet material with a pressure sensitive adhesive.

13. The method of claim 9, wherein coating the first surface of the thermal absorption sheet material comprises arranging the EMI absorption powder mixture in a unidirectional pattern onto the thermal absorption sheet material.

14. The method of claim 9, wherein the metal comprises at least one of iron, aluminum, and chromium.

15. An electronic device, comprising:
a heat producing electronic component; and
a hybrid sheet material proximate the heat producing electronic component and comprising:
an electromagnetic interference (EMI) absorption layer comprising a first binder material, silicon, and at least one metal; and
a thermal absorption layer bonded to at least one surface of the EMI absorption layer, the thermal absorption layer comprising a graphite material and a second binder.

16. The electronic device of claim 15, wherein the heat producing electronic component is a display panel.

17. The electronic device of claim 15, further comprising a near field communication (NFC) antenna and wherein the heat producing electronic component is a battery positioned adjacent the NFC antenna.

18. The electronic device of claim 17, further comprising an adhesive material positioned between the battery and the NFC antenna and between the EMI absorption layer of the hybrid sheet material and the NFC antenna.

19. The electronic device of claim 15, wherein the metal of the EMI absorption layer comprises at least one of iron, aluminum, and chromium.

20. The electronic device of claim 15, wherein the electronic device is a mobile device.
